(19) United States
(12) Patent Application Publication
(10) Pub. No.: US 2019/0350087 A1
(43) Pub. Date: Nov. 14, 2019

(54) CLEANING METHOD AND SYSTEM

(71) Applicant: ASELSAN ELEKTRONIK SANAYI VE TICARET ANONIM SIRKETI, Ankara (TR)

(72) Inventors: Basar BOLUKBAS, Ankara (TR); Emre MERT, Ankara (TR)

(73) Assignee: ASELSAN ELEKTRONIK SANAYI VE TICARET ANONIM SIRKETI, Ankara (TR)

(21) Appl. No.: 16/476,081

(22) PCT Filed: Feb. 6, 2018
(86) PCT No.: PCT/TR2018/050043

§ 371 Date: Jul. 4, 2019

(30) Foreign Application Priority Data
Mar. 28, 2017 (TR) 2017/04622

(51) Int. Cl. H05K 3/26; B08B 7/00; H05K 1/03

(52) U.S. Cl. CPC H05K 3/26; H05K 3/10; H05K 1/03; B08B 7/0028

(57) ABSTRACT

A cleaning system and a cleaning method to clean the paste overflowing from at least one hole on the substrate on to at least one substrate during the production of ceramics sintered together at low temperature. The cleaning system includes at least one adhesive tape that adheres to the paste and is convenient for placing over the substrate and at least one pressing element which presses the adhesive tape towards the substrate in order for the adhesive tape to adhere to the overflowing paste. The cleaning method includes laying at least one adhesive tape over the substrate; pressing the adhesive tape towards the substrate by at least one pressing element and enabling the adhesion of the adhesive tape to the paste overflowing from the hole; and separation of the adhesive tape that adheres on the paste overflowing from the hole.

### CROSS REFERENCE TO THE RELATED APPLICATIONS

This application is the national phase entry of International Application No. PCT/TR2018/050043, filed on Feb. 6, 2018, which claims priority from Turkish Patent Application 2017/04622, filed on Mar. 28, 2017, the entire contents of which are incorporated herein by reference.

### TECHNICAL FIELD

The present invention is related with a cleaning method and cleaning system to clean the paste which overflows the substrate during the production of ceramics sintered together at low temperature.

### BACKGROUND

Low temperature co-fired ceramic (LTCC) technology is particularly used in the manufacture of multilayer microwave module production. The production method of the ceramics which are sintered together at low temperature includes the steps of obtaining a substrate material, creating holes on the substrate material, filling the mentioned holes with a conductive paste, stacking different substrate materials one on top of the other and creating a multilayered structure, and sintering the created multilayered structure together. Here, in the step of filling conductive paste in the mentioned holes, the mentioned paste should not overflow outside of the hole. If conductive paste overflows the hole, the overflown conductive paste remains between the substrate materials which are stacked one on top of the other and deformations and/or bumps occur. Although the mentioned conductive paste is filled in the holes very precisely, circumstances of overflowing during the filling operation cannot be avoided. Therefore, the paste overflown on the substrate is required to be cleared off.

The ceramic sublayers which are sintered together at low temperature and a production method for the mentioned sublayers is described in the patent document numbered US2010059255A1 of the previous art. The mentioned method uses a diffusion barrier layer to prevent overflowing of the conductive paste from the hole. Although the method described in the patent document numbered US2010059255A1 prevents overflowing of conductive paste from one of the sublayers, the overflowing of paste from another layer cannot be avoided

### SUMMARY

The present invention is related with a cleaning system and a cleaning method to clean the paste which overflows at least one hole on at least one substrate during the production of ceramics sintered together at low temperature. The mentioned cleaning system includes at least one adhesive tape that adheres on the paste which overflows the hole and which is convenient for placing over the substrate and at least one pressing element which presses the mentioned adhesive tape towards the substrate.

The cleaning method developed with the present invention includes laying at least one adhesive tape over the substrate, pressing the adhesive tape towards the substrate by at least one pressing element, and enabling the adhesion of the adhesive tape to the paste that overflows the hole, and separation of the adhesive tape that adheres on the paste from the substrate.

In the cleaning system and the cleaning method developed with the present invention, the mentioned paste is separated from the substrate as a result of the adhesion of the paste which overflows the hole on the substrate to the adhesive tape. Furthermore, as a result of pressing the adhesive tape towards the substrate by means of the mentioned pressing element, the adhesive tape is enabled to adhere better to the paste that overflows the hole. As a result, the paste that overflows the substrate through the hole can easily and reliably be cleaned.

The present invention develops a cleaning method and a cleaning system to clean the paste which overflows the substrate during the production of ceramics sintered together at low temperature.

Another objective of the invention is to develop a practical and reliable cleaning method and cleaning system.

### BRIEF DESCRIPTION OF THE DRAWINGS

Certain embodiments of the cleaning method and the cleaning system developed with the present invention are shown on the annexed figures, wherein;

FIG. 1 is a perspective view of one form of use of the developed cleaning system.

FIG. 2 is a perspective view of another form of use of the developed cleaning system.

The parts on the figures have been numbered one by one, and these numbers refer to the following items:
Substrate (1)
Adhesive tape (2)
Pressing element (3)
Body (3a)
Roller (3b)
Handle (3c)
Hole (4)

### DETAILED DESCRIPTION OF THE EMBODIMENTS

Holes are created on a substrate material and the mentioned holes are filled with conductive paste during the production of ceramics which are sintered together at low temperature. After that, different substrate materials are stacked one on the other and a multilayered structure is formed, and the created multilayered structure is sintered. The paste that overflows the holes during these processes may result in deformations. Therefore, the present invention develops a cleaning method and a cleaning system to clean the paste which overflows the substrate during the production of ceramics sintered together at low temperature.

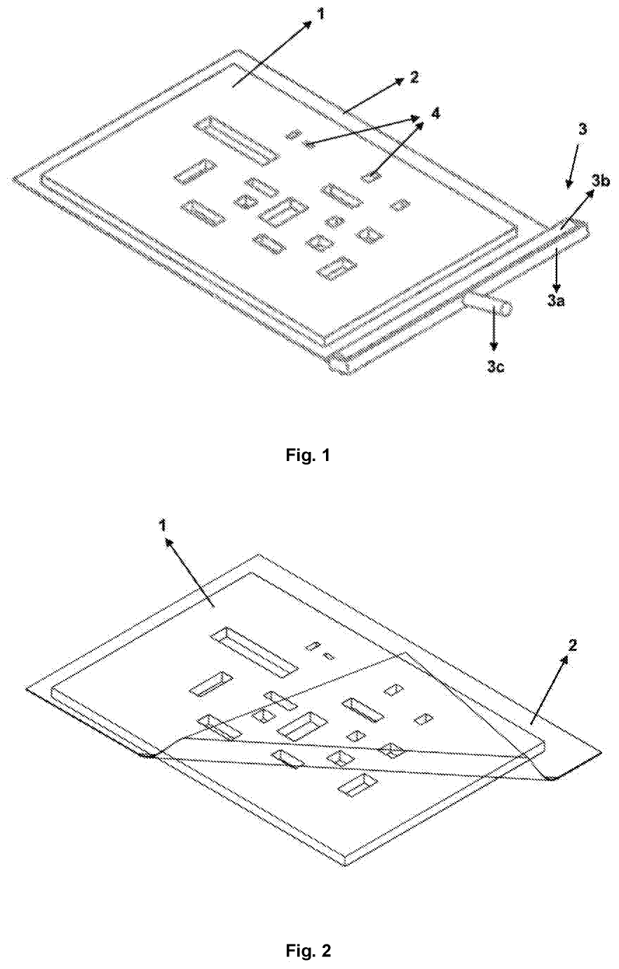

The cleaning system developed with the prevent invention with certain embodiments given in FIGS. 1 and 2 includes at least one preferably flexible adhesive tape (2) which is convenient for placing over the substrate (1) and adheres on the paste that overflows the hole (4) on the substrate (1) and one pressing element (3) which presses the mentioned adhesive tape (2) towards the substrate to enable the mentioned adhesive tape (2) to adheres on the paste which overflows the hole (4) on the substrate (1).

The cleaning method developed with the present invention includes laying at least one adhesive tape (2) over the substrate (1) (so that the adhesive side faces the substrate (1)), pressing the adhesive tape (2) towards the substrate (1) by at least one pressing element (3), and enabling the adhesion of the adhesive tape (2) to the paste that overflows the hole (4), and separation of the adhesive tape (2) that adheres on the paste that overflows the hole (4) from the substrate (1).

In an exemplary embodiment of the invention, after the conductive paste is filled in at least one hole (4) on the substrate (1), the mentioned adhesive tape (2) is laid on the substrate (1) so that the adhesive side faces the substrate (1) in order to clean the paste that overflows the hole (4). The adhesive tape (2) mentioned here adheres to a layer with adhesive material on at least one surface (preferably a weak adhesive) (such as film). The mentioned pressing element (3) presses the adhesive tape (2) towards the substrate (1). As a result, the adhesive tape (2) adheres on the paste which overflows the hole (4). Finally, after the adhesive tape (2) detaches from the substrate (1), the paste that adheres on the adhesive tape (2) is removed from the substrate (1). As a result, the paste that overflows the substrate (1) is cleaned quickly, practically and reliably.

In one preferred application of the invention, the mentioned adhesive tape (1) is in transparent structure. As a result, after the step of pressing the adhesive tape (2) towards the substrate (1) by a pressing element (3), it can be observed whether the paste that overflows the hole (4) adheres on the adhesive tape (2). Here, if the paste that overflows the hole (4) does not adhere on the adhesive tape (2), the step of pressing the adhesive tape (2) towards the substrate (1) by the pressing element (3) may be repeated. As a result, adhesion of the paste that overflows the hole (4) to the adhesive tape (2) can be guaranteed.

In another preferred application of the invention, the mentioned pressing element (3) includes at least one body (3a) and at least one roller (3b) which is attached rotatably to the said body (3a). The said roller (3b) is preferably made of a flexible material such as rubber. The said pressing element (3) may also include at least one handle (3c) located on the body (3a). In this application, the user can roll the mentioned roller (3b) on the adhesive tape (2) by holding the body (3a) and/or the handle (3c). As a result, the mentioned pressing process is easily and practically realized.

In another application of the invention, during the step of separating the adhesive tape (2) from the substrate (1) after it adheres on the paste overflowing the hole (4), the adhesive tape (2) can be moved parallel to the substrate (1) as shown on FIG. 2. Here, the user holds one edge or corner of the mentioned tape (2) and pulls it in an axis parallel to one surface of the substrate (1). As a result, the movement and flexing of the substrate (1) during the separation of the adhesive tape (2) from the substrate (1) is prevented.

In the cleaning system and the cleaning method developed with the present invention, the mentioned paste is separated from the substrate (1) as the paste which overflows the hole (4) on the substrate (1) adheres to the adhesive tape (2). Furthermore, as a result of pressing the adhesive tape (2) towards the substrate (1) by means of the mentioned pressing element (3), the adhesive tape (2) is enabled to adhere better to the paste that overflows the hole (4). As a result, the paste that overflows the substrate (1) through the hole (4) can easily and reliably be cleaned.

What is claimed is:

1. A cleaning system to clean a paste overflowing from at least one hole, located on a substrate, onto at least one substrate during a production of ceramics sintered together at a low temperature, comprising:
at least one adhesive tape configured to be placed on the substrate and adhere to the paste overflowing from the at least one hole; and
at least one pressing element for pressing the at least one adhesive tape towards the substrate to enable adhesion of the at least one adhesive tape to the paste overflowing from the at least one hole.

2. The cleaning system according to claim 1, wherein, the at least one adhesive tape is transparent.

3. The cleaning system according to claim 1, wherein, the at least one pressing element comprises at least one body and at least one roller attached rotatably to the at least one body.

4. The cleaning system according to claim 3, wherein the at least one pressing element further comprises at least one handle on the at least one body.

5. A cleaning method to clean a paste overflowing from at least one hole, located on a substrate, onto at least one substrate during a production of ceramics sintered together at low temperature, comprising:
laying at least one adhesive tape onto the substrate;
pressing the at least one adhesive tape towards the substrate by means of at least one pressing element for enabling adhesion of the at least one adhesive tape to the paste overflowing from the at least one hole; and
separating the at least one adhesive tape from the substrate after the at least one adhesive tape adheres to the paste overflowing from the at least one hole.

6. The cleaning method according to claim 5, further comprising, after the step of pressing the at least one adhesive tape towards the substrate, observing whether the paste overflowing the at least one hole adheres on the at least one adhesive tape.

7. The cleaning method according to claim 6, wherein, if the paste overflowing from the at least one hole does not adhere on the at least one adhesive tape, repeating the step of pressing the at least one adhesive tape towards the substrate by the at least one pressing element.

8. The cleaning method according to claim 5, wherein, during the step of separating the at least one adhesive tape from the substrate, the at least one adhesive tape is moved parallel to the substrate.
